(19) United States
(12) Patent Application Publication
(10) Pub. No.: US 2009/0309201 A1
(43) Pub. Date: Dec. 17, 2009

(54) LEAD FRAME, SEMICONDUCTOR DEVICE, METHOD FOR MANUFACTURING LEAD FRAME AND METHOD FOR MANUFACTURING SEMICONDUCTOR DEVICE

(75) Inventor: Tomoki MORITA, Kanagawa (JP)

Correspondence Address: YOUNG & THOMPSON, 209 Madison Street, Suite 500, Alexandria, VA, 22314, US

(73) Assignee: NEC Electronics Corporation, Kanagawa (JP)

(21) Appl. No.: 12/478,074

(22) Filed: Jun. 4, 2009

(30) Foreign Application Priority Data
Jun. 11, 2008 (JP) 2008-153473

(51) Int. Cl. H01L 23/495; C23F 1/00; H01L 21/56

(52) U.S. Cl. 257/676; 216/14; 438/127; 257/E23.031; 257/E21.503

(57) ABSTRACT

A lead frame has a die pad on which a semiconductor chip is mounted, a plurality of leads, a first recess provided so as to sink in from the front surface of the die pad, and second recesses and third recesses (through holes) provided so as to sink in from the front surface and the rear surface of the leads, respectively. The inner wall surfaces of the first recess, the second recesses and the third recesses (through holes) are made uneven, respectively.

This application is based on Japanese patent application No. 2008-153473, the content of which is incorporated hereinto by reference.

### BACKGROUND

1. Technical Field

The present invention relates to a lead frame, a semiconductor device, a method for manufacturing a lead frame and a method for manufacturing a semiconductor device.

2. Related Art

In recent years, reduction in the size, resistance and cost have been demanded for the packages for semiconductor devices. In order to meet these demands, packages where a semiconductor chip is provided on a lead frame and the semiconductor chip is sealed in a sealing resin have been used in recent years. However, there is a great difference in the index of thermal expansion between the metal that forms the lead frame and the material for the sealing resin. Therefore, in the case where adhesion between the two is insufficient, peeling from the interface occurs and the sealing resin cracks, which are causes of the lowering of the reliability of the product. Therefore, techniques for increasing the surface area of the lead frame in order to increase adhesion between the two have been proposed.

Japanese Unexamined Patent Publication No. 2001-127232 describes, for example, the configuration of a lead frame where a plurality of through holes is created in the portion in which a semiconductor element is mounted through a punching process in order to increase the strength of adhesion between the sealing resin and the portion in which a semiconductor element is mounted in such a manner that the through holes are slits provided adjacent to each other, and the small pieces sandwiched between adjacent through holes are formed so as to be twisted relative to the direction in which the through holes are punched. As a result, it is described that the strength of adhesion between the portion in which a semiconductor element is mounted, such as a die pad, and the sealing resin can be increased.

In addition, Japanese Unexamined Patent Publication No. 2007-258587 describes, for example, a lead frame used for a semiconductor device where a semiconductor chip is mounted and sealed in a sealing resin and the surface of a portion of the lead frame sealed in the sealing resin is made uneven such that hooks are formed so as to extend in the direction that crosses the direction of the depth of the recesses.

However, the present inventors found the following problems with the related art.

In the case where the surface of a lead frame is made uneven as described in Japanese Unexamined Patent Publication No. 2007-258587, for example, it is possible for the adhesion between the lead frame and the sealing resin to increase. When portions of the surface of the leads are made uneven as described above, however, such a problem arises that the leads easily come off from the sealing resin. The present inventors found that the adhesion is low on the surface of the leads, which is not uneven, and therefore, the leads can rotate in the direction of the thickness of the lead frame, making it easy for the leads to come off from the sealing resin. In particular, this problem of leads coming off is significant in the type of semiconductor devices where leads are exposed and protrude to the outside of the sealing resin. In the technique described in Japanese Unexamined Patent Publication No. 2001-127232, through holes are provided only in the die pad, and there is still a problem with the leads coming off.

### SUMMARY

In one embodiment, there is provided a lead frame, including: a die pad on which a semiconductor chip is mounted; a plurality of leads arranged around the die pad at a distance from the die pad; a first recess provided so as to sink in from the front surface of the die pad; a plurality of second recesses provided so as to sink in from the front surface of the plurality of leads, respectively; and a plurality of third recesses provided so as to sink in from the rear surface of the plurality of leads, respectively, wherein the inner wall surfaces of the first recess, each of the second recesses and each of the third recesses are made uneven, respectively.

In another embodiment, there is provided a semiconductor device, including: a semiconductor chip; a lead frame which includes: a die pad at a front surface of which the semiconductor chip is mounted; a plurality of leads arranged around the die pad at a distance from the die pad; a first recess provided so as to sink in from the front surface of the die pad; a plurality of second recesses provided so as to sink in from the surface side of the plurality of leads, respectively; and a plurality of third recesses provided so as to sink in from the rear surface of the plurality of leads, respectively; and a sealing resin provided at the front surface of the lead frame to seal the semiconductor chip and fill the first recess, the plurality of second recesses and the plurality of third recesses, wherein the inner wall surfaces of the first recess, each of the second recesses and each of the third recesses are made uneven, respectively.

In another embodiment, there is provided a method for manufacturing a lead frame, including: forming a first resist film and a second resist film on the front surface and on the rear surface of a lead frame including a die pad on which a semiconductor chip is mounted and a plurality of leads arranged around the die pad at a distance from the die pad, respectively; creating a first opening at a first location corresponding to the die pad and a plurality of second openings at a plurality of second locations respectively corresponding to the plurality of leads in the first resist film; creating a plurality of third openings at a plurality of third locations respectively corresponding to the plurality of leads in the second resist film; creating a first recess provided so as to sink in from the front surface of the die pad, a plurality of second recesses provided so as to sink in from the front surface of the plurality of leads, respectively, and a plurality of third recesses provided so as to sink in from the rear surface of the plurality of leads, respectively, in the lead frame by etching the lead frame through isotropic etching using the first resist film and the second resist film as masks, wherein the first recesses, the second recesses and the third recesses are respectively created so as to have a form that the width of the opening expands along the direction from the surface toward the inside in which the recesses are created.

In another embodiment, there is provided a method for manufacturing a semiconductor device, including: mounting a semiconductor chip on the front surface of the die pad of the lead frame which is manufactured in accordance with the method for manufacturing a lead frame; and sealing the semiconductor chip by a sealing resin, and at the same time, filling the first recess, the plurality of second recesses and the plurality of third recesses with the sealing resin.

In these configurations, recesses are created on the front surface and on the rear surface of the leads and the inner wall surfaces of the recesses are made uneven, and therefore, when a semiconductor chip is mounted on the lead frame and the semiconductor chip is sealed in a sealing resin, adhesion between the die pad and the sealing resin is stronger and the leads can be effectively prevented from coming off from the sealing resin.

Any combination of the components and any modification of the methods and apparatuses by applying the present invention are also considered as modes of the present invention.

According to the present invention, when a semiconductor chip is mounted on a lead frame and the semiconductor chip is sealed in a sealing resin, adhesion between the die pad and the sealing resin is stronger and the leads can be prevented from coming off from the sealing resin.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a top view diagram showing the configuration of the lead frame according to an embodiment of the present invention;

FIG. 2 is a cross sectional diagram along A-A′ line in FIG. 1;

FIG. 3 is a top view diagram showing the configuration of the semiconductor device according to an embodiment of the present invention;

FIG. 4 is a cross sectional diagram along B-B′ line in FIG. 3;

FIGS. 5A to 5D, 6A to 6D and 7A to 7E are cross sectional diagrams showing the steps in the process for creating recesses in a lead frame according to an embodiment of the present invention;

FIGS. 8A, 8B and 9A, 9B are cross sectional diagrams showing the steps in the process for manufacturing a semiconductor device according to an embodiment of the present invention;

FIGS. 10A to 10C are cross sectional diagrams showing other examples of the configuration of the semiconductor device according to an embodiment of the present invention;

FIG. 11 is a top view diagram showing another example of the configuration of the semiconductor device according to an embodiment of the present invention;

FIG. 12 is a top view diagram showing another example of the configuration of the semiconductor device according to an embodiment of the present invention;

FIG. 13 is a top view diagram showing the configuration of the semiconductor device according to an embodiment of the present invention;

FIG. 14 is a cross sectional diagram along C-C′ line in FIG. 13; and

FIG. 15 is a cross sectional diagram showing another example of the semiconductor device shown in FIG. 13.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In the following, the embodiments of the present invention are described in reference to the drawings. In all the drawings, the same reference numerals are attached to the same components, and the descriptions thereof will not be repeated.

### First Embodiment

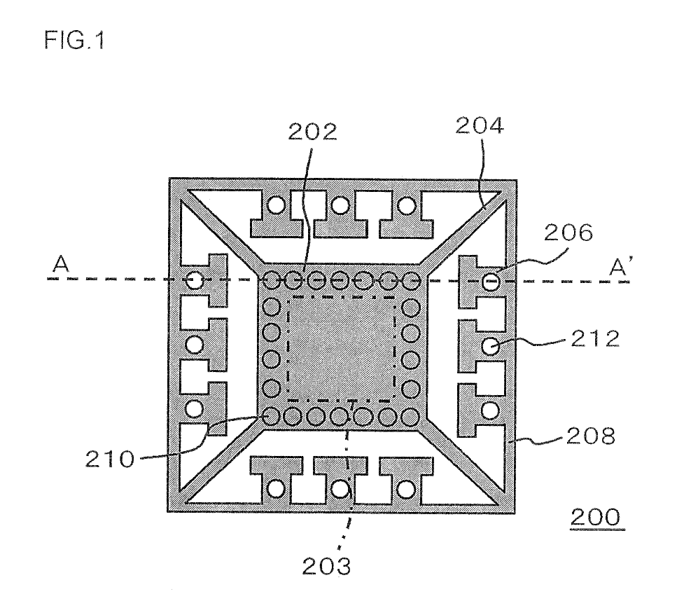

FIG. 1 is a top view diagram showing the configuration of the lead frame according to the present embodiment.

The lead frame 200 includes a die pad 202 on the front surface of which a semiconductor chip is to be mounted, support leads 204, a plurality of leads 206 and an outer frame 208. The die pad 202 has a rectangular form. The support leads 204 are provided at the four corners of the die pad 202. The die pad 202 is connected to the outer frame 208 via the support leads 204. In addition, the plurality of leads 206 is also connected to the outer frame 208. In this state, the die pad 202, the support leads 204, the leads 206 and the outer frame 208 are formed integrally. Here, the leads 206 have a T shape with the side close to the die pad 202 wider. This shape makes it difficult for the leads 206 to come off when the leads are sealed in the sealing resin later.

In the present embodiment, a semiconductor chip is to be provided in the chip placing region 203 (hereinafter, it is just referred to as “the region 203”) of the die pad 202. Here, a plurality of recesses 210 (first recesses) is provided around the region 203 of the die pad 202. In additions a plurality of through holes 212 (second recesses and third recesses) which penetrates from the front surface to the rear surface of the lead frame 200 is provided in the respective plurality of leads 206.

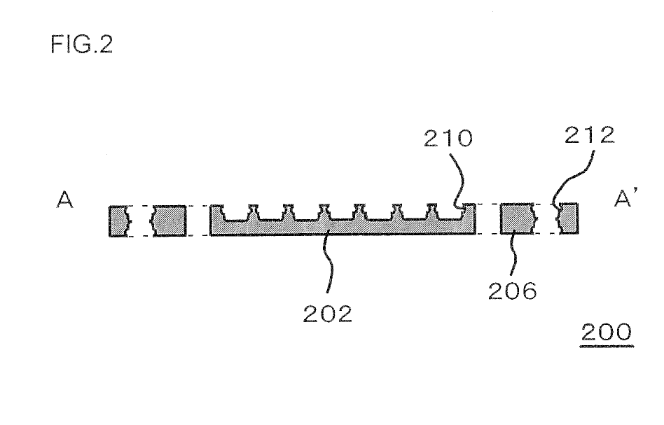

FIG. 2 is a cross sectional diagram along A-A′ line in FIG. 1.

In the present embodiment, the inner wall surfaces of the recesses 210 and the through holes 212 are made uneven. Here, they may be made uneven by forming at least one protrusion which protrudes from the rest in a portion of the inner wall surfaces, or by creating at least one recess which sinks in from the rest in a portion of the inner wall surfaces. That is to say, the unevenness may include a surface which is facing against the direction from the surface to the inside of the lead frame 200 (the direction in which the recess is created). In this configuration, the surface facing against the direction from the surface to the inside of the lead frame 200 become a hooking portion when the recesses 210 and the through holes 212 are filled in with a sealing resin, so that adhesion between the sealing resin and the lead frame 200 can be increased.

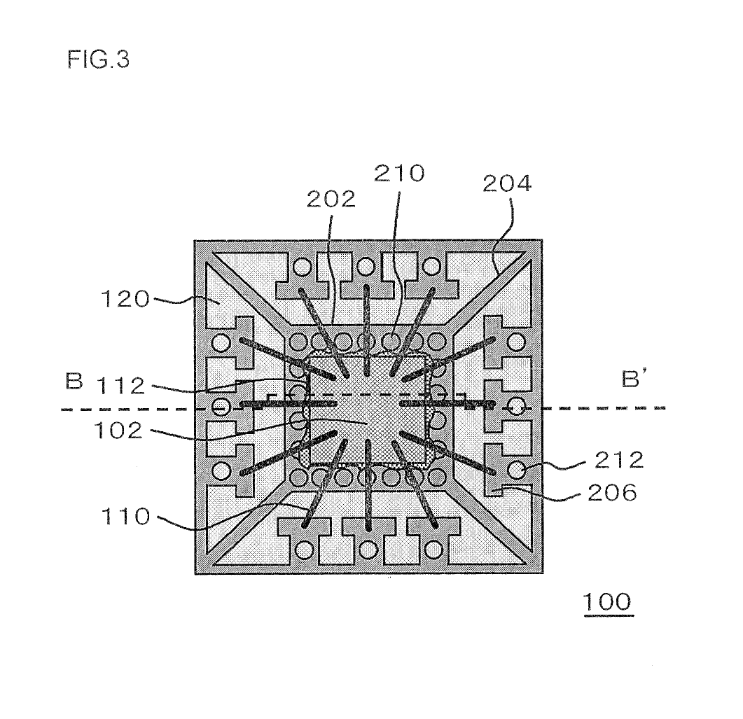

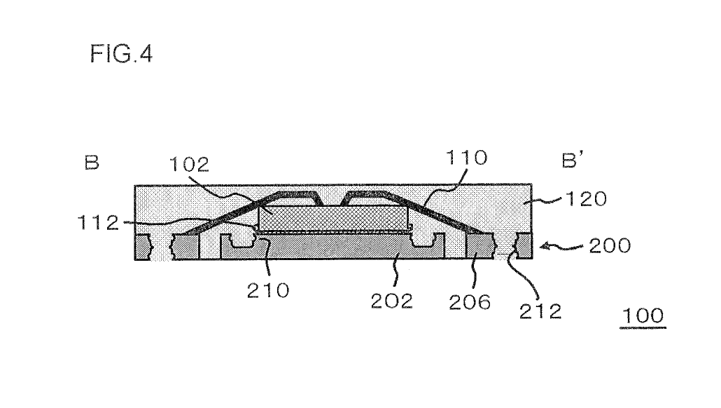

FIG. 3 is a top view diagram showing the configuration of the semiconductor device 100 according to the present embodiment. FIG. 4 is a cross sectional diagram along B-B′ line in FIG. 3.

Here, a semiconductor chip 102 is mounted on the die pad 202 of the lead frame 200 and pasted to the die pad 202 by means of a die bonding material 112. A plurality of electrode pads (not shown) of the semiconductor chip 102 and the plurality of leads 206 are electrically connected via bonding wires 110. The lead frame 200, the semiconductor chip 102 and the bonding wires 110 are buried and sealed in a sealing resin 120. The sealing resin 120 may be made of an epoxy resin, for example. At this time, the recesses 210 and the through holes 212 are also filled in with the sealing resin 120.

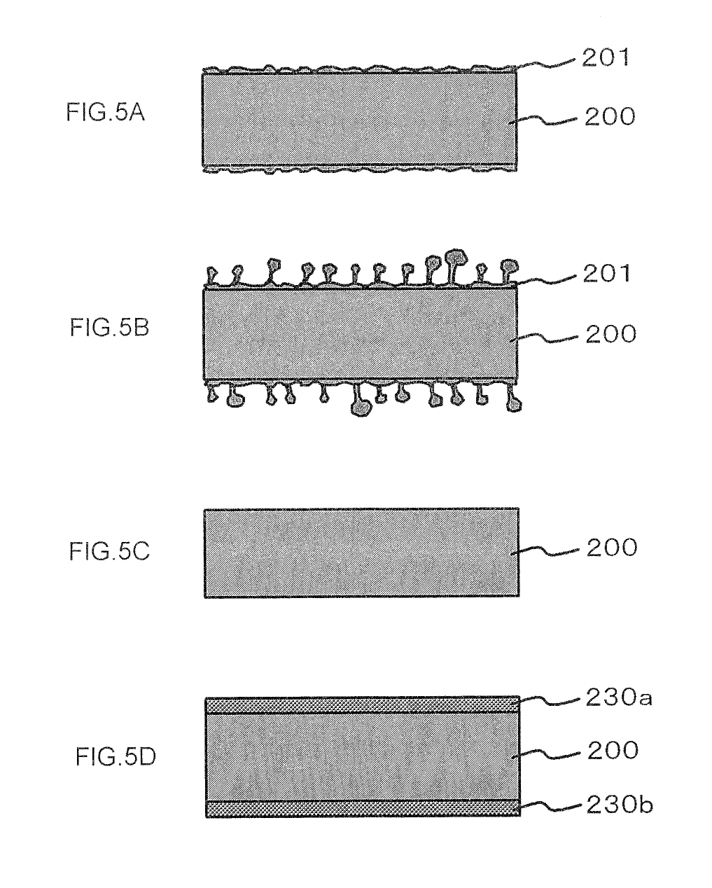

FIGS. 5A to 5D, 6A to 6D, and 7A to 7E are cross sectional diagrams showing the steps in a process for creating the recesses 210 and the through holes 212 in the lead frame 200 according to the present embodiment. FIG. 5A is a diagram showing the lead frame 200 before the recesses 210 and the through holes 212 are created. Here, the lead frame 200 has a plane shape as shown in FIG. 1 though the recesses 210 and the through holes 212 are not provided yet.

In the present embodiment, the recesses 210 and the through holes 212 may be created through half etching, with which recesses can be created in the lead frame 200 by etching it in the direction from the surface to the inside. Through holes 212 may be created by half etching the lead frame 200 from both the front surface and the rear surface of the lead frame 200.

First, a preprocess, for example washing and baking, is carried out on the lead frame 200. The deposit material 201, such as foreign substance, oil or an oxide film, that deposits on the lead frame 200 is removed by immersing the lead frame 200 in a cleaning liquid (FIGS. 5A to 5C). After that, baking is carried out to improve adhesion with the resist which will be used in the following steps.

Next, the front surface (upper side in the figures) and the rear surface (lower side in the figures) of the lead frame 200 are coated with a resist 230a and a resist 230b, respectively, followed by prebaking (FIG. 5D). The solvent in the resist evaporates during the prebaking, so that the density of the resist 230a and the resist 230b increases.

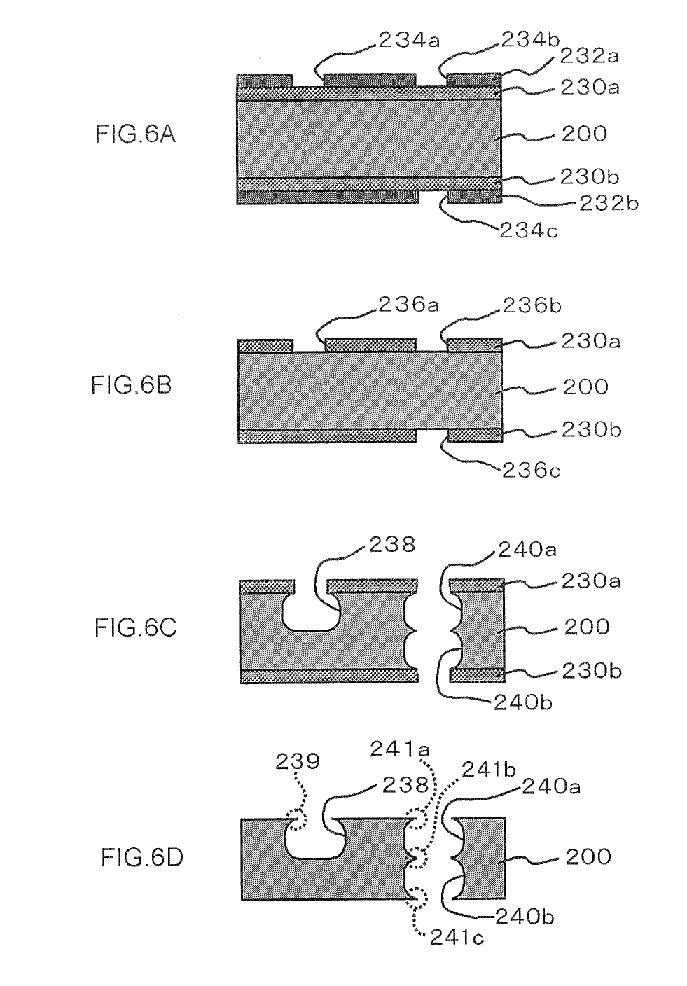

Next, a mask for exposure to light 232a and a mask for exposure to light 232b are placed on the resist 230a and the resist 230b, respectively (FIG. 6A). The mask for exposure to light 232a has openings 234a provided at locations corresponding to recesses 210 in the die pad 202 shown in FIG. 1, and openings 234b provided at locations corresponding to through holes 212 in the leads 206 shown in FIG. 1. The mask for exposure to light 232b has openings 234c provided at locations corresponding to the through holes 212 in the leads 206 shown in FIG. 1. That is to say, the openings 234b in the mask for exposure to light 232a and the openings 234c in the mask for exposure to light 232b are provided at locations which face each other.

The resist 230a and the resist 230b are exposed to light and developed using the mask for exposure to light 232a and mask for exposure to light 232b, respectively, as masks. As a result, the pattern of the mask for exposure to light 232a and the mask for exposure to light 232b is transferred to the resist 230a and the resist 230b, respectively. That is to say, openings 236a and openings 236h are created in the resist 230a at locations corresponding to the openings 234a and the openings 234b, respectively, in the mask for exposure to light 232a. In addition, openings 236c are created in the resist 230b at locations corresponding to the openings 234c in the mask for exposure to light 232b (FIG. 6B). In the present embodiment, the openings 234a, the openings 234b and the openings 234c may be circular in a plan view. Therefore, the openings 236a, the openings 236b and the openings 236c created in the resist 230a and the resist 230b may also be circular in a plan view.

Here, the pattern of the resist 230a and the resist 230b is checked after development, and post baking is carried out, unless there is a problem. Post baking is carried out in order to remove the water in the remaining developer and rinsing solution, as well as in order to increase the adhesion of the resist 230a and the resist 230b to the lead frame 200, and the resistance to etching in the following step.

Next, the lead frame 200 is half etched using the resist 230a and the resist 230b as masks, so that recesses 238 recesses 240a and recesses 240b are created in the lead frame 200 (FIG. 6C). Here, the recesses 238, the recesses 240a and the recesses 240b have such a form that the width (diameter) expands along the direction from the surface toward the inside in which the recesses are created. That is to say, in the present embodiment, the recesses 238, the recesses 240a and the recesses 240b have such a form that the diameter inside the lead flame 200 is greater than the diameter of the openings 236a, the openings 236b and the openings 236c created in the resist 230a and the resist 230b used as masks, respectively. In order to gain such a form, the recesses 238, the recesses 240a and the recesses 240b may be created through isotropic etching, for example through wet etching. As a result, the etching progresses in an isotropic manner, the side etching occurs, and recesses having a greater inside diameter, so that the deeper part from the surface bulges out, can be created. As the etchant, a ferric chloride solution may be used, for example.

After that, the resist 230a and the resist 230b are removed using a peeling solution. In the present embodiment, the recesses 238 are created through isotropic etching, and thus, the recesses 238 have such a form that protrusions 239 are formed in the portion on the surface of the lead frame 200. Likewise, the recesses 240a have such a form that protrusions 241a are formed in the portion on the surface of the lead frame 200. In addition, the recesses 240h have such a form that protrusions 241c are formed in the portion on the rear surface of the lead frame 200. Furthermore, in the present embodiment, each of the recesses 240a and each of the recesses 240b are provided to be communicating with each other to create a through hole in the leads 206 (FIG. 6D). Further, by creating the recesses 240a and the recesses 240b through isotropic etching from the front surface and the rear surface of the lead frame 200, through holes are created in such a form that protrusions 241b are formed in the portions of the boundaries between the two recesses. Through the process, the inner wall surfaces of the recesses 238 and the through holes created as a recess 240a and a recess 240b are made uneven.

Furthermore, half etching steps may be repeated in order to form more protrusions.

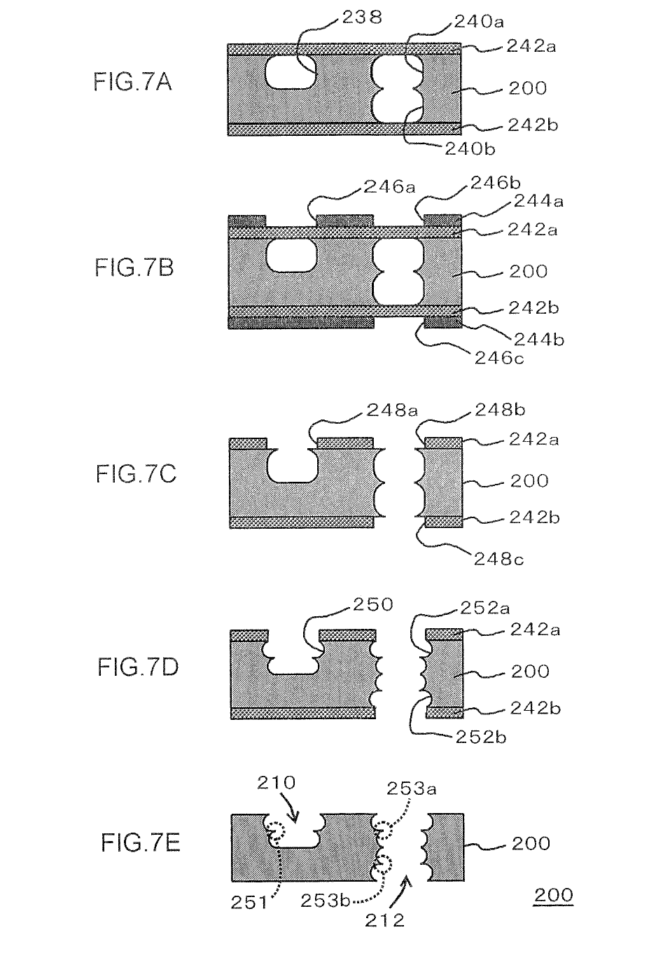

As shown in FIG. 7A, the resist 242a and the resist 242b are again provided on the front surface (upper side in the figure) and on the rear surface (lower side in the figure) respectively, of the lead frame 200. Here, recesses have already been created in the lead frame 200, and therefore, films may be used as the resist 242a and the resist 242h in order not to be filled in the recesses.

Next, a mask for exposure to light 244a and a mask for exposure to light 244b are provided on the resist 242a and the resist 242b, respectively (FIG. 7B). The mask for exposure to light 244a is provided with openings 246a and openings 246b at locations corresponding to the openings 234a and the openings 234b, respectively, in the mask for exposure to light 232a. In addition, the mask for exposure to light 244b is provided with openings 246c at locations corresponding to the openings 234c in the mask for exposure to light 232b. Here, the openings 246a in the mask for exposure to light 244a are wider than the openings 234a in the mask for exposure to light 232a. Likewise, the openings 246b in the mask for exposure to light 244a are wider than the openings 234b in the mask for exposure to light 232a. As well, the openings 246c in the mask for exposure to light 244b are wider than the openings 234c in the mask for exposure to light 232b.

The resist 242a and the resist 242b are exposed to light and developed using the mask for exposure to light 244a and the mask for exposure to light 244b, respectively, as masks. As a result, the pattern of the mask for exposure to light 244a and the mask for exposure to light 244b is transferred to the resist 242a and the resist 242b, respectively. That is to say, openings 248a and openings 248b are created in the resist 242a at locations corresponding to the openings 246a and the openings 246b, respectively, in the mask for exposure to light 244a. In addition, the openings 248c are created in the resist 242b at locations corresponding to the openings 246c in the mask for exposure to light 244b (FIG. 7C).

Next, the lead frame 200 is etched using the resist 242a and the resist 242b as masks. Here, isotropic etching, for example wet etching, may be carried out. In addition, the time for etching can be made approximately half of the time for creating the recesses 238, the recesses 240a and the recesses 240b. As a result, recesses 250 having a greater diameter and shallower than the recesses 238 can be created within the recesses 238. At the same time, recesses 252a having a greater diameter and shallower than the recesses 240a can be created within the recesses 240a. In addition, recesses 252b having a greater diameter and shallower than the recesses 240b can be created within the recesses 240b (FIG. 7D).

After that, the resist 242a and the resist 242b are removed using a peeling solution or the like. Thus, recesses 210 can be created at the front surface side of the lead frame 200. In addition, through holes 212 can be created in the lead frame 200. In the present embodiment, half etching through isotropic etching is repeated to create recesses and through holes in steps, and thus, a plurality of protrusions can be formed within the recesses 210 and the through holes 212. Protrusions 251 are formed in the portions of the boundary between a recess 238 and a recess 250 within the recesses 210, in addition to the protrusions 239, as shown in FIG. 6D. Likewise, protrusions 253a and protrusions 253b are formed within the through holes 212, in addition to the protrusions 241a, the protrusions 241b and the protrusions 241c, as shown in FIG. 6B (FIG. 7E). Through the process, the inner wall surfaces of the recesses 210 and the through holes 212 are made uneven.

In addition, the same half etching steps are repeated, and thus, the inner wall surfaces of the recesses 210 and the through holes 212 can be made highly uneven. Thus, recesses and through holes are created through half etching, and the inner wall surfaces can be made uneven as desired without using any specific die or the like. In addition, recesses can be created simultaneously from the front surface and the rear surface of the lead frame 200 without affecting the opposite side.

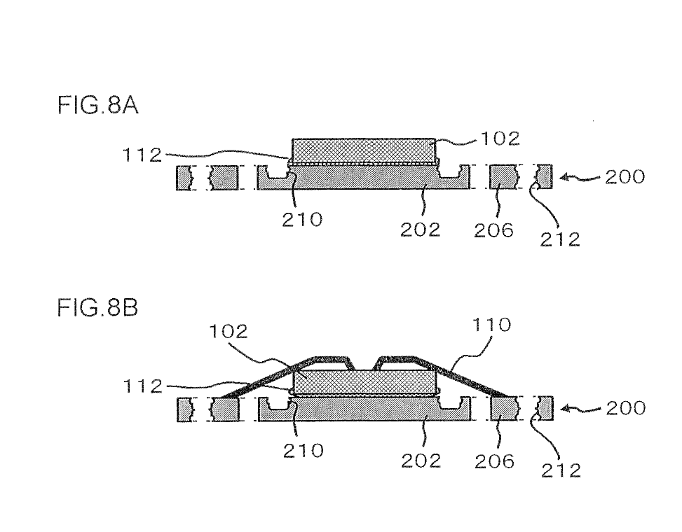

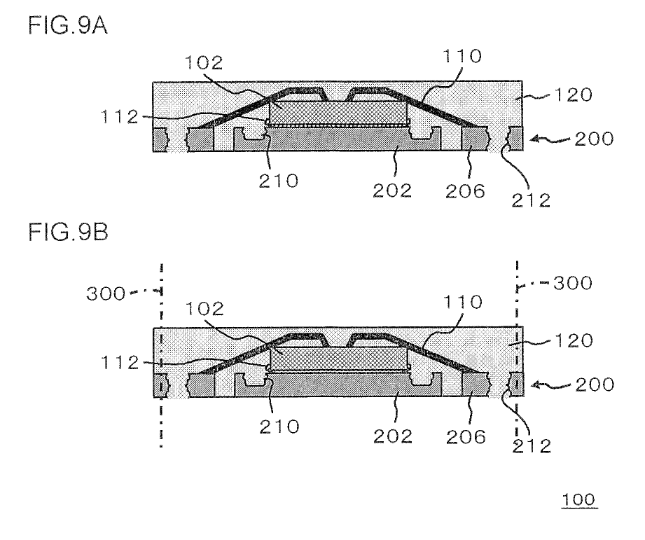

FIGS. 8A to 9B are cross sectional diagrams showing the steps in a process for manufacturing a semiconductor device 100 by mounting a semiconductor ship 102 on a lead frame 200 and then sealing it in a sealing resin 120.

First, a semiconductor chip 102 is mounted on the die pad 202 using a die bonding material 112 (FIG. 8A). Next, the semiconductor chip 102 and the lead 206 are electrically connected using bonding wires 110 (FIG. 8B). Next, the lead frame 200, the semiconductor chip 102 and the bonding wires 110 are sealed in a sealing resin 120 (FIG. 9A). At this time, the recesses 210 and the through holes 212 in the lead frame 200 are filled in with the sealing resin 120. As a result, the area of adhesion between the lead frame 200 and the sealing resin 120 increases, so that the adhesion between the two increases. After that, a blade or a die is used to cut the semiconductor device out from the lead frame 200 along the broken lines 300 (FIG. 9B). At this time, the outer frame of the lead frame 200 is cut and removed, so that the leads 206 are separated from the die pad 202. Through the process, the semiconductor device 100 according to the present embodiment can be obtained.

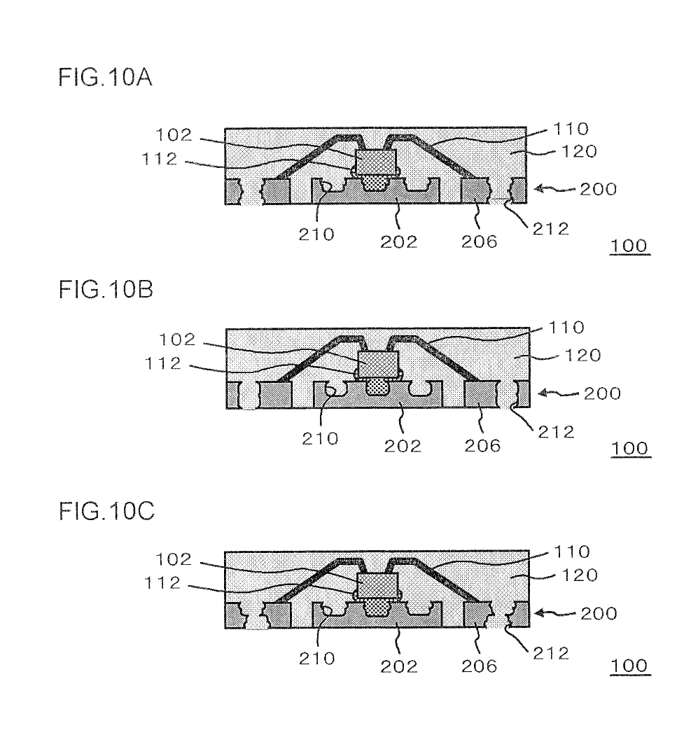

FIGS. 10A to 10C are cross sectional diagrams showing other examples of the configuration of the semiconductor device 100 according to the present embodiment.

FIG. 10A is a cross sectional diagram showing an example where recesses 210 are created in the region 203 of the die pad 202 (see FIG. 1). Here, though for the sake of simplicity, an example where only one recess 210 is created beneath the semiconductor chip 102 is shown, a plurality of recesses 210 may be provided beneath the semiconductor chip 102 in accordance with the size of the semiconductor chip 102 and the size of the recesses 210. As in the present example, recesses 210 are provided in the region 203, and thus, the adhesion between the die pad 202 and the die bonding material 112 can be increased.

FIG. 10B is a cross sectional diagram showing an example where recesses 210 and through holes 212 are created by carrying out the half etching step only once in order to create recesses and through holes in the lead frame 200. This is an example of a case where etching of the lead frame 200 is complete in such a state that the recesses 238, the recesses 240a and the recesses 240b are created as in FIG. 6D. Thus, protrusions, for examples protrusions 239, protrusions 241a, protrusions 241b and protrusions 241c, are formed in the recesses 210 and the through holes 212, so that the adhesion between the sealing resin 120 and the lead frame 200 can be made appropriate. Half etching can be carried out any number of times, taking the adhesion between the lead frame material and sealing material used and cost into account. Here, though an example where recesses 210 are created in the region 203 of the die pad 202 in which a chip is provided as in FIG. 10A is shown, a configuration where no recesses 210 are created in the region 203, as in the examples shown in FIGS. 1 and 9A to 9B, can be used.

FIG. 10C is a cross sectional diagram showing an example where through holes 212 are created by recesses formed from the front surface and formed from the rear surface of the lead frame 200 where parts of them do not overlap in a plane view. In this configuration, the axis line of the through holes 212 is not linear. As a result, the inside of the through holes 212 can be made more uneven, so that the adhesion between the lead frame 200 and the sealing resin 120 can be increased. Here, though an example where recesses 210 are created in the region 203 of the die pad 202 is shown, as in FIG. 10A, a configuration where no recesses 210 are created in the region 203 as in the examples shown in the drawings 1 to 9(b), may be used.

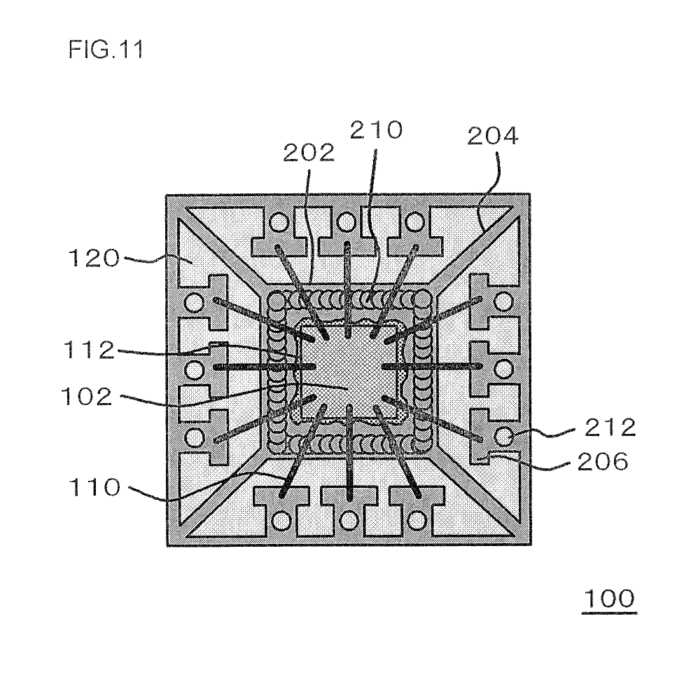

FIG. 11 is a top view diagram showing another example of the configuration of the semiconductor device 100 according to the present embodiment.

In the present example, continuous recesses are provided in the outer peripheral portion of the region 203 of the die pad 202. Thus, the recesses 210 are arranged so as to be connected in a toroidal form in the outer peripheral portion of the region 203 of the die pad 202 in which a chip is provided. Here, the recesses 210 in a toroidal form are filled in with a sealing resin 120.

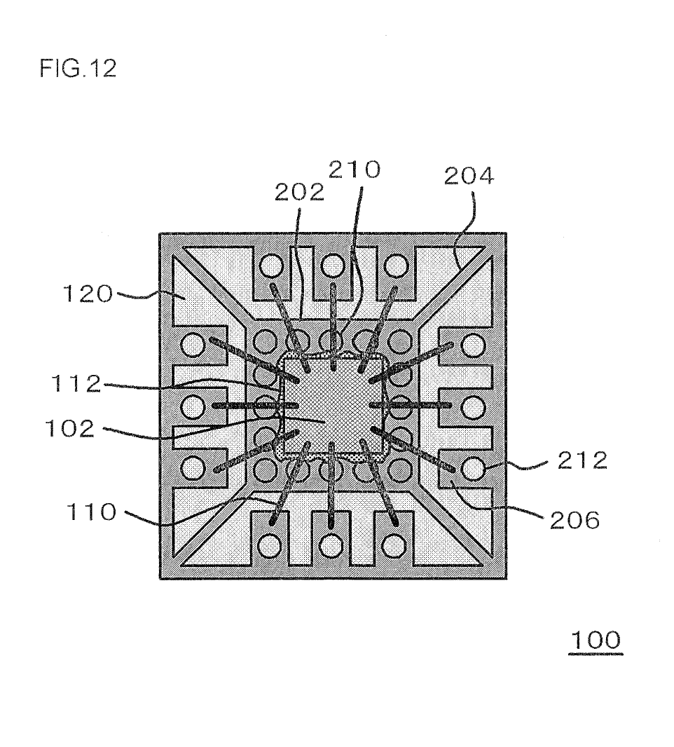

FIG. 12 is a top view diagram showing another example of the configuration of the semiconductor device 100 according to the present embodiment.

In the present example, the leads 206 are in a rectangular form. In the present embodiment, through holes 212 are created in the leads 206, so that the through holes 212 are filled in with a sealing resin 120, and thus, the adhesion between the leads 206 and the sealing resin 120 can be increased. Therefore, the leads 206 can be prevented from coming off from the sealing resin 120 even when the leads 206 are in a rectangular form. Thus, the size of the leads 206 can be reduced, and at the same time, becomes possible to reduce the pitch of the leads, making miniaturization of the package possible.

The following effects can be obtained from the lead frame according to the present embodiment.

In the present embodiment, through holes 212 of which the inner wall surfaces are made uneven are created in the leads 206, and therefore, the adhesion between the leads 206 and the sealing resin 120 becomes high at both sides of the leads 206: the front surface and the rear surface. Therefore, the leads 206 can be prevented from coming off from the sealing resin 120.

In addition, recesses 210 which are not through holes and do not penetrate are created in the die pad 202. Therefore, the die bonding material 112 can be prevented from flowing out to the rear surface of the lead frame 200. Thus, the semiconductor chip 102 mounted on the die pad 202 can be of any size. Furthermore, the recesses 210 are not through holes, and thus, there are no limitations in terms of the arrangement of the recesses 210. Thus, the recesses 210 can be arranged throughout the entire surface on the front surface of the die pad 202, as shown in FIGS. 10A to 10C.

Furthermore, in the present embodiment, recesses and through holes can be created through half etching, and thus, the inner wall surfaces can be made uneven as desired in a simple process, without using a die or the like, described in Japanese Unexamined Patent Publication No. 2001-127232 and Japanese Unexamined Patent Publication No. 2007-258587.

### Second Embodiment

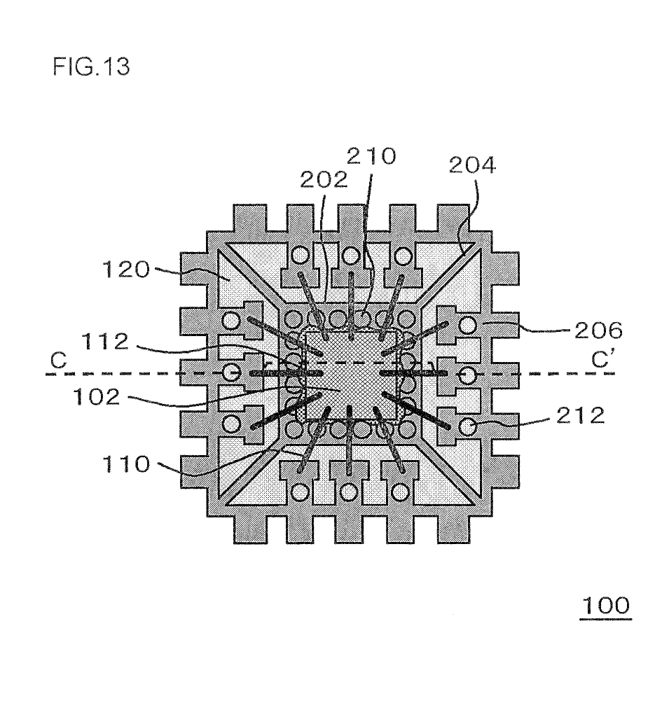

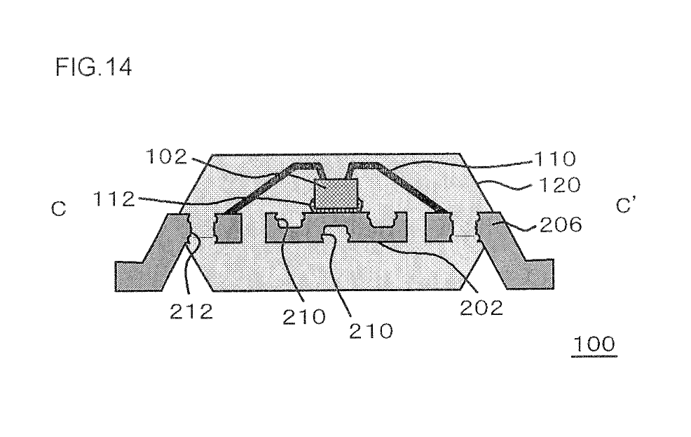

FIG. 13 is a top view diagram showing the configuration of a semiconductor device according to the present embodiment. FIG. 14 is a cross sectional diagram along line C-C′ line in FIG. 13.

The configuration of the semiconductor device in the present embodiment is different from that of the semiconductor device 100 in the first embodiment in that leads 206 are exposed from the sealing resin 120, and the sealing resin 120 covers the rear surface of the lead frame 200 as well.

In the case of this configuration, recesses 210 can be provided at the rear surface side of the die pad 202 as well. As a result, the recesses 210 formed from the rear surface of the die pad 202 are filled in with the sealing resin 120, so that the area of adhesion between the lead frame 200 and the sealing resin 120 can be increased at the rear surface of the die pad 202. As a result, it is possible to increase the adhesion between the lead frame 200 and the sealing resin 120 in packages having a configuration where the rear surface of the die pad 202 is not exposed, but sealed in the sealing resin 120.

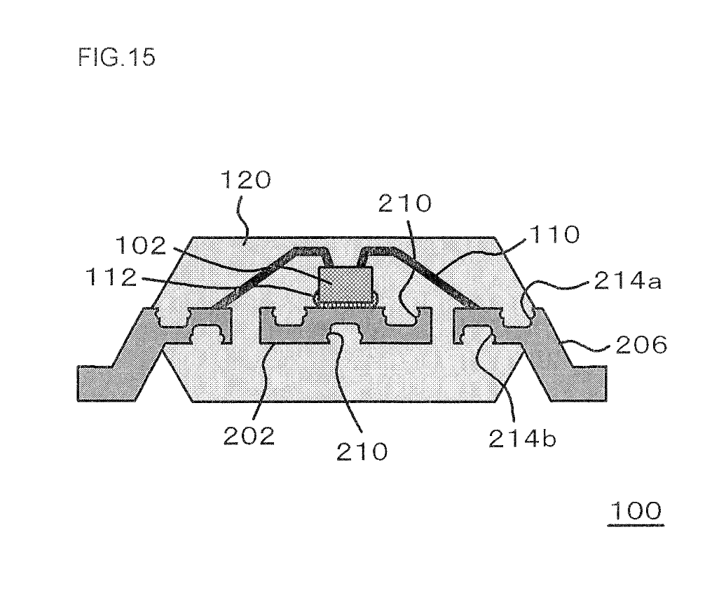

FIG. 15 is a cross sectional diagram showing another example of the configuration of the semiconductor device 100 according to the present embodiment. In the case of a configuration where a sealing resin 120 is provided at the rear surface of the lead frame 200, as in the semiconductor device 100 according to the present embodiment, the leads 206 can be provided with recesses 214a and recesses 214b at the front surface and the rear surface, respectively, instead of through holes 212. In this configuration also, the adhesion between the leads 206 and the sealing resin 120 is high on both sides of the leads 206: the front surface and the rear surface. Thus, the leads 206 can be prevented from coming off from the sealing resin 120.

Though in the above the embodiments of the present invention are described in reference to the drawings, they are exemplary according to the present invention and various configurations other than the above can be adopted.

In all the examples described above, leads 206 can be in a rectangular form in the same manner as in the description in reference to FIG. 12.

In addition, when a half-etching step is carried out two or more times, the mask for half-etching may have an opening of which the location of the center is shifted from that of the opening created previously, and thus, the recess or the through hole can be in such a form that the axis line is not linear.

The above embodiments illustrate such examples where recesses 210, which are not through holes and do not penetrate through the substrate, are created in the die pad 202. However, through holes may be provided in the die pad 202. That is to say, recesses may be created from the rear surface of the lead frame 200 so as to be connected to the recesses 210 in the die pad 202. In particular, such through holes can be provided in the die pad 202 in an area around the region 203.

It is apparent that the present invention is not limited to the above embodiments, and may be modified and changed without departing from the scope and spirit of the invention.

What is claimed is:

1. A lead frame, comprising:
a die pad on which a semiconductor chip is mounted;
a plurality of leads arranged around said die pad at a distance from said die pad;
a first recess provided so as to sink in from the front surface of said die pad;
a plurality of second recesses provided so as to sink in from the front surface of said plurality of leads, respectively; and
a plurality of third recesses provided so as to sink in from the rear surface of said plurality of leads, respectively,
wherein the inner wall surfaces of said first recess, each of said second recesses and each of said third recesses are made uneven, respectively.

2. The lead frame according to claim 1, wherein in each of said plurality of leads, said second recess and said third recess are provided as communicating with each other to create a through hole that penetrates from the front surface to the rear surface of said lead.

3. The lead frame according to claim 2, wherein in each of said plurality of leads, said second recess and said third recess are provided in such locations that at least parts of said second recess and said third recess do not overlap in a plan view.

4. The lead frame according to claim 1, wherein in each of said plurality of leads, said second recess and said third recess are provided in different locations in a plan view and are provided as not communicating with each other.

5. The lead frame according to claim 1, wherein said first recess, each of said second recesses and each of said third recesses are created through isotropic etching and respectively have such a form that the width of the opening expands along the direction from the surface toward the inside in which the recesses are created.

6. The lead frame according to claim 1, further comprising a fourth recess provided so as to sink in from the rear surface of said die pad.

7. The lead frame according to claim 1, further comprising a plurality of said first recess, said plurality of first recesses being provided at a region around the region in which said semiconductor chip is mounted on said die pad.

8. A semiconductor device, comprising:
a semiconductor chip;
a lead frame which includes: a die pad at a front surface of which said semiconductor chip is mounted; a plurality of leads arranged around said die pad at a distance from said die pad; a first recess provided so as to sink in from the front surface of said die pad; a plurality of second recesses provided so as to sink in from the surface side of said plurality of leads, respectively; and a plurality of third recesses provided so as to sink in from the rear surface of said plurality of leads, respectively; and
a sealing resin provided at the front surface of said lead frame to seal said semiconductor chip and fill said first recess, said plurality of second recesses and said plurality of third recesses,
wherein the inner wall surfaces of said first recess, each of said second recesses and each of said third recesses are made uneven, respectively.

9. The semiconductor device according to claim 8, wherein in each of said plurality of leads, said second recess and said third recess are provided as communicating with each other to create a through hole that penetrates from the front surface to the rear surface of said lead.

10. The semiconductor device according to claim 9, wherein in each of said plurality of leads, said second recess and said third recess are provided in such locations that at least parts of said second recess and said third recess do not overlap in a plan view.

11. The semiconductor device according to claim 8, wherein in each of said plurality of leads, said second recess and said third recess are provided in different locations in a plan view and are provided as not communicating with each other.

12. The semiconductor device according to claim 8, wherein said first recess, each of said second recesses and each of said third recesses are created through isotropic etching and respectively have such a form that the width of the opening expands along the direction from the surface toward the inside in which the recesses are created.

13. The semiconductor device according to claim 8, wherein said sealing resin is provided also at the rear surface of said lead frame.

14. The semiconductor device according to claim 13, wherein said lead frame further includes a fourth recess provided so as to sink in from the rear surface of said die pad, said sealing resin filling said fourth recess.

15. The semiconductor device according to claim 8, wherein said lead frame includes a plurality of said first recess, said plurality of first recesses being provided at a region around the region in which said semiconductor chip is mounted on said die pad.

16. A method for manufacturing a lead frame, comprising:
forming a first resist film and a second resist film on the front surface and on the rear surface of a lead frame including a die pad on which a semiconductor chip is mounted and a plurality of leads arranged around said die pad at a distance from said die pad, respectively;
creating a first opening at a first location corresponding to said die pad and a plurality of second openings at a plurality of second locations respectively corresponding to said plurality of leads in said first resist film;
creating a plurality of third openings at a plurality of third locations respectively corresponding to said plurality of leads in said second resist film;
creating a first recess provided so as to sink in from the front surface of said die pad, a plurality of second recesses provided so as to sink in from the front surface of said plurality of leads, respectively, and a plurality of third recesses provided so as to sink in from the rear surface of said plurality of leads, respectively, in said lead frame by etching said lead frame through isotropic etching using said first resist film and said second resist film as masks,
wherein said first recesses, said second recesses and said third recesses are respectively created so as to have a form that the width of the opening expands along the direction from the surface toward the inside in which the recesses are created.

17. The method for manufacturing a lead frame according to claim 16, further comprising:
forming a third resist film and a fourth resist film on the front surface and on the rear surface of said lead frame, respectively, after said steps of isotropic etching using said first resist film and said second resist film as masks;
creating a fourth opening which is wider than said first opening at a fourth location corresponding to said die pad and a plurality of fifth openings which are wider than said plurality of second openings at a plurality of fifth locations respectively corresponding to said plurality of leads in said third resist film;
creating a plurality of sixth openings which are wider than said plurality of third openings at a plurality of sixth locations respectively corresponding to said plurality of leads in said fourth resist film; and
etching said lead frame through isotropic etching using said third resist film and said fourth resist film as masks,
wherein in said etching said lead frame using said third resist film and said fourth resist film as masks, the time for etching is set shorter than that in said etching said lead frame using said first resist film and said resist film as masks to form shallower recesses of which the openings are wider are created within said first recess, each of said plurality of second recesses and each of said plurality of third recesses, respectively.

18. A method for manufacturing a semiconductor device, comprising:
mounting a semiconductor chip on the front surface of said die pad of said lead frame which is manufactured in accordance with the method for manufacturing a lead frame according to claim 16; and
sealing said semiconductor chip by a sealing resin, and at the same time, filling said first recess, said plurality of second recesses and said plurality of third recesses with said sealing resin.
